(19) United States
(12) Patent Application Publication
(10) Pub. No.: US 2002/0132469 A1
(43) Pub. Date: Sep. 19, 2002

(54) Method for forming metal wiring layer

(75) Inventors: Jong-Myeong Lee, Sungnam-city (KR); Byung-Hee Kim, Seoul (KR); Myoung-Bum Lee, Seoul (KR); Ju-Young Yun, Seoul (KR); Gil-Heyun Choi, Sungnam-city (KR)

Correspondence Address: Anthony P. Onello, Jr., MILLS & ONELLO LLP, Eleven Beacon Street, Suite 605, Boston, MA, 02108, US

(73) Assignee: Samsung Electronics Co; Ltd.

(21) Appl. No.: 09/915,104

(22) Filed: Jul. 25, 2001

(30) Foreign Application Priority Data
Mar. 13, 2001 (KR) 01-12900

(51) Int. Cl. H01L 21/4763; H01L 21/31; H01L 21/469

(52) U.S. Cl. 438/628; 438/618; 438/760

(57) ABSTRACT

A metal wiring layer of a semiconductor device in which a nucleation liner is formed prior to forming an aluminum liner. A barrier metal layer is formed on a semiconductor substrate. A nucleation liner for growing an aluminum layer is formed on the barrier metal layer in a vacuum state. An aluminum liner is formed by growing an aluminum layer on the nucleation liner using chemical vapor deposition in a vacuum state in situ with the step of forming the nucleation liner. A metal layer is formed on the aluminum liner using physical vapor deposition. The semiconductor substrate is heat-treated and reflowed.

### BACKGROUND OF THE INVENTION

1. Field of the Invention

The present invention relates to a method for manufacturing a semiconductor integrated circuit, and more particularly, to a method for forming a metal wiring layer.

2. Description of the Related Art

As the integration density of semiconductor devices increases, it becomes necessary to introduce metal wiring layers having a multilayered structure into the semiconductor circuits. Since metal wiring layers transmit electrical signals, it is necessary to use a material for the metal wiring layers that has low electrical resistance and high reliability, and is economical. To meet these demands, aluminum is widely used for the material of the metal wiring layers.

However, as line width of a circuit decreases, there are technical limits in applying conventional deposition techniques to form a metal wiring layer in a process for manufacturing a semiconductor device. Thus, a technique of filling either a contact hole connecting a lower conductive layer to an upper aluminum wiring layer or a via hole connecting a lower aluminum wiring layer to an upper aluminum wiring layer, with a wiring material, is considered to be very important to electrically interconnect the layers to each other.

To obtain superior electrical properties and filling characteristics when filling the contact hole or via hole (hereinafter, only the contact hole will be mentioned) with aluminum, a variety of processing techniques have been developed. In a deposition process for forming a metal wiring layer in the manufacture of a next generation memory device, in which the line width of a circuit is no greater than 0.25 pm, the aspect ratio of a contact hole is high, and thus it is improper to completely rely on a physical vapor deposition (PVD) process, such as sputtering. To overcome the problem of a high aspect ratio of a contact hole, various studies have been conducted on processes for forming the aluminum wiring layer using chemical vapor deposition (CVD), which has superior step coverage characteristics, as compared to the characteristics of PVD.

In a process for depositing aluminum using CVD, a precursor which is an aluminum compound is used as an aluminum source. However, current precursors used to form the aluminum layer exhibit selective deposition characteristics. In other words, the deposition characteristics of the current precursors vary depending on the surface state of an object to be deposited in a CVD process. If a conventional technique of forming a metal wiring layer is directly applied to the case of forming an aluminum wiring layer of such a precursor, it is very difficult to form an aluminum layer having a uniform thickness along the surface of a contact hole or a via hole, and thus reproducibility, and therefore reliability, is adversely affected.

### SUMMARY OF THE INVENTION

To address the above limitations, it is an object of the present invention to provide a method for forming a metal wiring layer, by forming an aluminum layer for filling a contact hole or via hole using a chemical mechanical deposition method, in a manner that is reliably reproducible.

Accordingly, to achieve the above object, there is provided a method for forming a metal wiring layer of a semiconductor device. A barrier metal layer is formed on a semiconductor substrate. A nucleation liner for growing an aluminum layer is formed on the barrier metal layer in a vacuum state. An aluminum liner is formed by growing an aluminum layer on the nucleation liner using chemical vapor deposition in situ with the step of forming the nucleation liner. A metal layer is formed on the aluminum liner by using physical vapor deposition. The semiconductor substrate including the metal layer is reflowed by heat-treating the metal layer in a vacuum state.

The method for forming a metal wiring layer of a semiconductor device may further comprise the step of forming a resistant metal layer on the semiconductor substrate before the step of forming the barrier metal layer.

Also, the method for forming a metal wiring layer of a semiconductor device may further comprise the step of heat-treating the barrier metal layer after the step of forming the barrier metal layer.

The nucleation liner may be formed of one of a refractory metal and a refractory metal compound, such as a Ti layer, a TiN layer or a Ti/TiN layer. The nucleation liner may be formed by chemical vapor deposition or physical vapor deposition. Preferably, the nucleation liner includes a Ti-rich TiN layer. The Ti-rich TiN layer may be formed by chemical vapor deposition using H₂ plasma or sputtering. The nucleation liner is formed to have a thickness of 10-100 Å.

Preferably, the step of forming the metal layer is performed in a vacuum state which has been maintained since the formation of the aluminum liner. The metal layer is formed of one of aluminum and an aluminum alloy.

The method for forming a metal wiring layer of a semiconductor device according to the present invention may further comprise the step of forming an interlayer dielectric layer to define a hole region on the semiconductor substrate before the step of forming the barrier metal layer, in which case the barrier metal layer is formed on the semiconductor substrate including the interlayer dielectric layer.

According to the present invention, when manufacturing a highly-integrated semiconductor device having a high aspect ratio contact hole or via hole, it is possible to form an aluminum liner at a uniform thickness on a nucleation liner by chemical vapor deposition. Therefore, a contact hole or via hole for forming metal wiring layers can be completely filled, and thus the reliability of a semiconductor device can be enhanced.

### BRIEF DESCRIPTION OF THE DRAWINGS

The above object and advantages of the present invention will become more apparent by describing in detail a preferred embodiment thereof with reference to the attached drawings in which:

FIGS. 1 through 6 are cross-sectional views illustrating a method for forming a metal wiring layer of a semiconductor device according to an embodiment of the present invention.

### DETAILED DESCRIPTION OF PREFERRED EMBODIMENTS

The present invention will now be described more fully with reference to the accompanying drawings, in which a preferred embodiment of the invention is shown. This invention may, however, be embodied in many different forms and should not be construed as being limited to the embodiment set forth herein. Rather, the embodiment is provided so that this disclosure will be thorough and complete, and will fully convey the concept of the invention to those skilled in the art. In the drawings, the thickness of layers and regions are exaggerated for clarity. It will also be understood that when a layer is referred to as being “on” another layer or substrate, it can be directly on the other layer or substrate, or intervening layers may also be present.

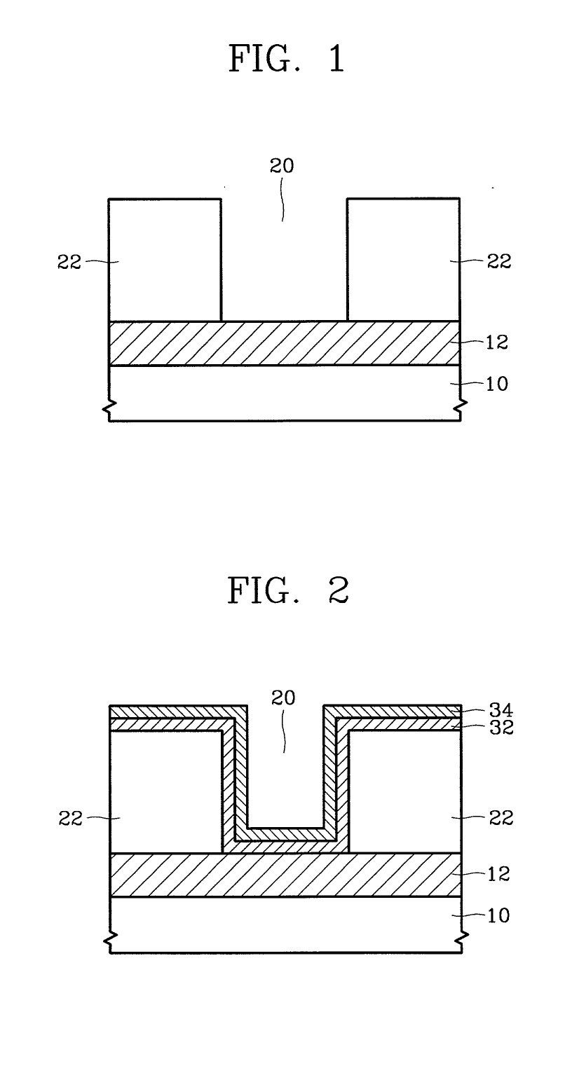

FIGS. 1 through 6 are cross-sectional views illustrating a method for forming a metal wiring layer of a semiconductor device according to an embodiment of the present invention. Referring to FIG. 1, an interlayer dielectric layer 22 is formed on a semiconductor substrate 10 on which a conductive region 12 is exposed so as to define a hole region 20. The interlayer dielectric layer 22 is preferably formed, for example, of a borophosphosilicate glass (BPSG) layer or an undoped silicon oxide layer.

The conductive region 12 may be a source/drain region or a conductive layer constituting transistors to be formed on the semiconductor substrate 10. In this case, the hole region 20 will become a contact hole. The conductive region 12 may be a metal wiring layer, in which case, the hole region 20 will become a via hole. As illustrated in FIG. 1, the conductive region 12 is exposed by the hole region 20. The hole region 20, however, may be a groove for forming a damascene wiring layer. In this case, the groove has a depth less than the thickness of the interlayer dielectric layer 22, and thus the groove does not expose the underlying conductive region 12.

Referring to FIG. 2, a resistant metal layer 32 and a barrier metal layer 34 are sequentially formed on the semiconductor substrate 10 including the interlayer dielectric layer 22. The resistant metal layer 32 is, for example, formed of Ti or Ta, preferably Ti. The barrier metal layer 34 is, for example, formed of TiN, TaN, TiAIN, TiSiN, TaAIN, TaSiN, or WN, preferably TiN.

The barrier metal layer 34 is preferably heat-treated. In a case where the conductive region 12 is a source/drain region, metal atoms in the resistant metal layer 32 react with silicon atoms in an impurity layer so that a metal silicide layer is formed and a phenomenon referred to as an “oxygen stuffing” effect simultaneously occurs in that a grain boundary region of the barrier metal layer 34 is filled with oxygen atoms. As described above, if the barrier metal layer 34 is heat-treated, contact resistance is enhanced due to the metal silicide layer formed between the conductive region 12 and the barrier metal layer 34, and it is possible to prevent silicon atoms in the conductive region 12, and aluminum atoms in a metal layer formed in a subsequent process, from passing through the barrier metal layer 34 and diffusing into each other's layer. Accordingly, in a case where the conductive region 12 forms a metal wiring layer, in other words, in a case where the hole region 20 is a via hole exposing a metal wiring layer, the steps of forming the barrier metal layer 34 and heat-treating the barrier metal layer 34 may be omitted. Also, in a case where the hole region 20 is a groove for forming a damascene wiring layer, the steps of forming the barrier metal layer 34 and heat-treating the barrier metal layer 34 may be omitted.

The barrier metal layer 34 is heat-treated in a nitrogen atmosphere at a temperature of 400-550° C. for approximately 30 minutes to 1 hour or is performed using a rapid thermal annealing process in an ammonia (NH₃) atmosphere at a temperature of 650-850° C. The rapid thermal annealing process is preferably performed for about 30 seconds to 2 minutes.

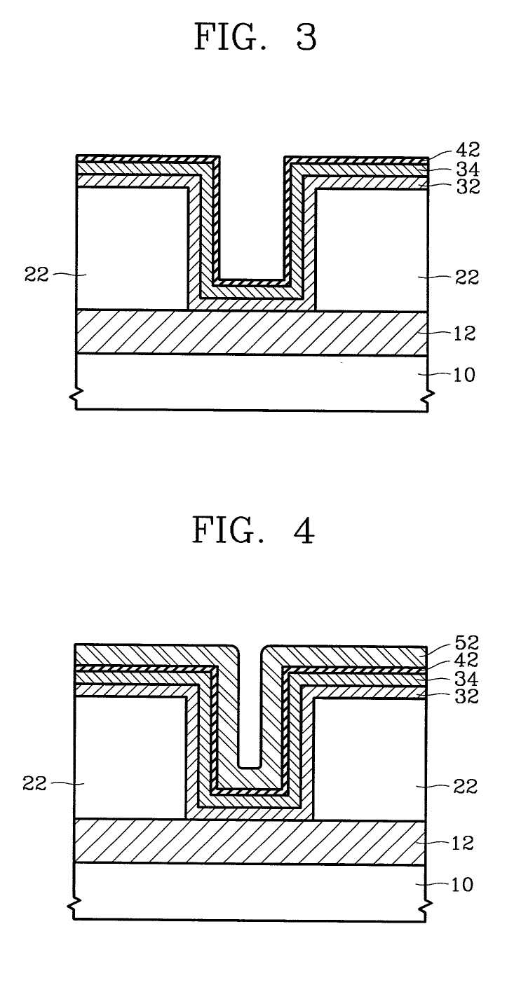

Referring to FIG. 3, a nucleation liner 42 is formed on the barrier metal layer 34. The nucleation liner 42 is formed to improve the surface state of the barrier metal layer on which an aluminum layer, which is to be formed in a subsequent process by CVD using a precursor as an aluminum source, is deposited, so that the aluminum layer can be reproducibly formed. Thus, the nucleation liner 42 does not have to be formed past a predetermined thickness. The nucleation liner 42 is formed to have a thickness of 10-100 Å, preferably, 10-50 Å.

The nucleation liner 42 is formed of a refractory metal or a refractory metal compound. Preferably, the nucleation liner 42 is formed of a Ti layer, a TiN layer, or a Ti/TiN layer. In a case where the nucleation liner 42 includes a TiN layer, the TiN layer is formed of a Ti-rich TiN layer. Here, the Ti-rich TiN layer indicates a TiN layer having an atom ratio of Ti atoms to N atoms of 1 or more (Ti/N>1). In other words, the amount of Ti existing in the Ti-rich TiN layer exceeds the stoichiometric proportion. Usually, barrier metal layers are formed of an N-rich TiN layer. However, the nucleation liner 42 is formed of the Ti-rich TiN layer because the Ti-rich TiN layer shows a conductivity that is superior to that of a typical TiN layer forming a barrier metal layer and because aluminum is more easily deposited on the Ti-rich TiN layer so that a very well shaped aluminum liner 52, which is formed of aluminum in a subsequent process by CVD (refer to FIG. 4), can be obtained.

To form the Ti-rich TiN layer forming the nucleation liner 42, CVD or PVD may be used. For example, the Ti-rich TiN layer may be formed by metal organic chemical vapor deposition (MOCVD) using H₂ plasma. In this process, hydrogen radicals generated from H₂ plasma supplied in a remote plasma chamber react with an organotitanium precursor used as a titanium source, for example, alkylamidotitanium derivatives, such as tetrakis-dimethylamidotitanium (TDMAT) or tetrakisdiethylamidotitanium (TDEAT), to form the Ti-rich TiN layer.

The nucleation liner 42 may be formed in a PVD process which is capable of obtaining superior step coverage, such as collimator sputtering, self-ionized plasma sputtering, or hollow cathode magnetron (HCM) sputtering. For example, in a case where the nucleation liner 42 is formed of a mixed layer of a Ti layer and a Ti-rich TiN layer by HCM sputtering, a Ti layer is formed using a titanium target in a sputtering chamber at a pressure of 1-20 mTorr and at a temperature between room temperature and 200° C. and then, a Ti-rich TiN layer is formed under the same conditions as the Ti layer with an addition of a small amount of nitrogen into the sputtering chamber.

Referring to FIG. 4, an aluminum liner 52 is formed on the nucleation liner 42 by CVD to have a thickness of about 10-200 Å. The step of forming the aluminum liner 52 as well as the steps of forming the nucleation liner 42 are performed in situ in a vacuum state. For this, integrated cluster tool type equipment, in which both a reaction chamber used for the formation of the nucleation liner 42 and a reaction chamber used for formation of the aluminum liner 52 are installed, is used.

For example, the aluminum liner 52 is formed by selective MOCVD. The selective MOCVD process is performed using a precursor formed of a organometallic compound, such as dimethylaluminum hydride (DMAH), trimethylamine alane (TMAA), dimethylethylamine alane (DMEAA), or methylpyrrolidine alane (MPA), as an aluminum source at a deposition temperature of 100-300° C., preferably, 120° C., and a pressure of 0.5-5 Torr, preferably, 1 Torr. At this time, to feed the precursor into a CVD chamber, a bubbler, a vapor flow controller, or a liquid delivery system may be used. An inert gas, such as Ar, is used as a dilution gas. To promote the decomposition of the precursor, a reaction gas, such as hydrogen gas, may be added.

Since the step of forming the aluminum liner 52 is performed in situ in a vacuum state after the step of forming the nucleation liner 42 is completed, it is possible to reproducibly form the aluminum liner 52 at a uniform thickness.

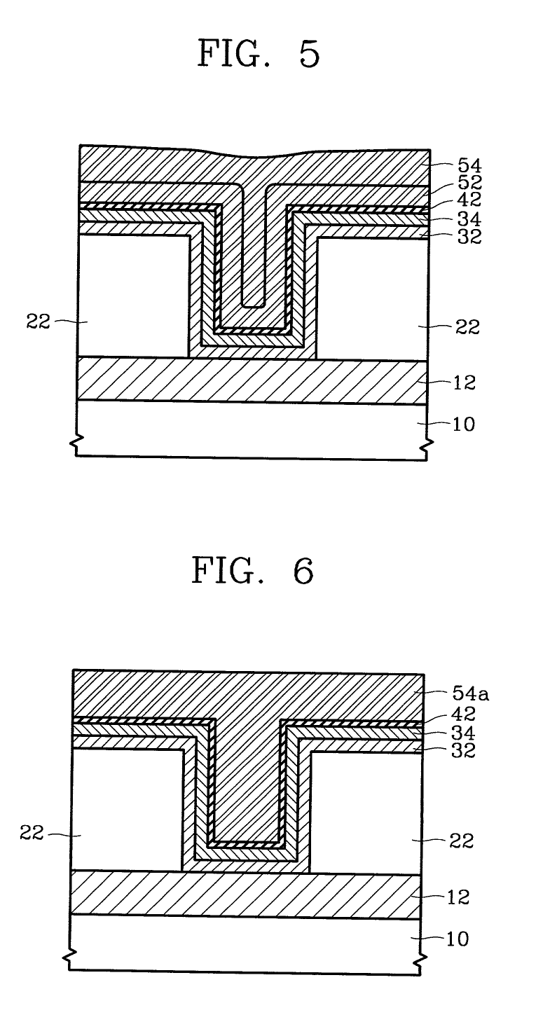

Referring to FIG. 5, a metal layer 54 is formed on the semiconductor substrate including the aluminum liner 52 to completely fill the hole region 20 defined by the aluminum liner 52. The metal layer 54 is formed by PVD. The metal layer 54 is preferably formed of aluminum or an aluminum alloy.

To form the metal layer 54, PVD, such as direct current (DC) sputtering, DC magnetron sputtering, or alternating current (AC) magnetron sputtering, may be used. Preferably, the metal layer 54 is formed by DC magnetron sputtering. The step of forming the metal layer 54 is performed by using integrated cluster tool type equipment and by maintaining a vacuum state continuing from the step of forming the aluminum liner.

Referring to FIG. 6, the semiconductor substrate including the metal layer 54 is heat-treated and reflowed in an inert gas atmosphere, for example, using Ar, under vacuum, at a temperature of 350-500° C. for several seconds to several minutes, preferably, 30-180 seconds. The heat treatment is preferably performed in a state where the surface of the metal layer 54 cannot be easily oxidized. Thus, the heat treatment is preferably performed in a high-vacuum state, the pressure of which is no greater than 1 Torr, preferably no greater than 10⁻⁶ Torr.

As described with reference to FIG. 3, in a case where the nucleation liner 42 is formed of a Ti-rich TiN layer, TiAl₃ is generated between the Ti-rich TiN layer and the aluminum liner 52 in the heat treatment described with reference to FIG. 6. As a result, the degree of movement of aluminum atoms in the aluminum liner 52 is restricted so that the original shape of the aluminum liner 52 can be maintained after the heat treatment is completed.

As a result of heat-treating the semiconductor substrate including the metal layer 54 under conditions described above, the metal layer 54 flows over the hole region 20 so as to completely fill the hole region 20 without a void. Then, a metal layer 54a having a planarized top surface is formed.

In the present invention, when a contact hole or a via hole is filled by a metal layer in order to form an aluminum wiring layer, a nucleation liner is formed before an aluminum liner is formed by CVD so that the aluminum liner can be reproducibly deposited on the nucleation liner. The steps of forming the nucleation liner and forming the aluminum liner are preferably performed in situ in a vacuum state. Thus, in the case of manufacturing a highly-integrated semiconductor device having a high aspect ratio contact hole or via hole, an aluminum liner can be reproducibly formed to have a uniform thickness by CVD, and accordingly the contact hole or via hole for forming of a metal wiring layer can be completely filled. In addition, the reliability of such a semiconductor device can be enhanced.

While this invention has been particularly shown and described with reference to preferred embodiments thereof, it will be understood by those skilled in the art that various changes in form and details may be made therein without departing from the spirit and scope of the invention as defined by the appended claims.

What is claimed is:

1. A method for forming a metal wiring layer of a semiconductor device comprising:
forming a barrier metal layer on a semiconductor substrate;
forming a nucleation liner for growing an aluminum layer on the barrier metal layer in a vacuum state;
forming an aluminum liner by growing an aluminum layer on the nucleation liner using chemical vapor deposition in situ with forming the nucleation liner;
forming a metal layer on the aluminum liner using physical vapor deposition; and
reflowing the semiconductor substrate including the metal layer by heat-treating the metal layer in a vacuum state.

2. The method for forming a metal wiring layer of a semiconductor device of claim 1, further comprising forming a resistant metal layer on the semiconductor substrate before forming the barrier metal layer.

3. The method for forming a metal wiring layer of a semiconductor device of claim 2, wherein the resistant metal layer is formed of one of Ti and Ta.

4. The method for forming a metal wiring layer of a semiconductor device of claim 1, wherein the barrier metal layer is formed of one of TiN, TaN, TiAIN, TiSiN, TaAIN, TaSiN, and WN.

5. The method for forming a metal wiring layer of a semiconductor device of claim 1, further comprising heat-treating the barrier metal layer after forming the barrier metal layer.

6. The method for forming a metal wiring layer of a semiconductor device of claim 5, wherein the step of heat-treating the barrier metal layer is performed in a nitrogen atmosphere at a temperature of 400-550° C.

7. The method for forming a metal wiring layer of a semiconductor device of claim 5, wherein the barrier metal layer is heat-treated by a rapid thermal annealing process.

8. The method for forming a metal wiring layer of a semiconductor device of claim 7, wherein the rapid thermal annealing process is performed in an ammonia (NH₃) atmosphere at a temperature of 650-850° C.

9. The method for forming a metal wiring layer of a semiconductor device of claim 1, wherein the nucleation liner is formed of one of a refractory metal and refractory metal compound.

10. The method for forming a metal wiring layer of a semiconductor device of claim 9, wherein the nucleation liner is formed of one of a Ti layer, a TiN layer and a Ti/TiN layer.

11. The method for forming a metal wiring layer of a semiconductor device of claim 1, wherein the nucleation liner is formed by one of chemical vapor deposition and physical vapor deposition.

12. The method for forming a metal wiring layer of a semiconductor device of claim 9, wherein the nucleation liner includes a Ti-rich TiN layer.

13. The method for forming a metal wiring layer of a semiconductor device of claim 12, wherein the Ti-rich TiN layer is formed by chemical vapor deposition using H₂ plasma.

14. The method for forming a metal wiring layer of a semiconductor device of claim 12, wherein the Ti-rich TiN layer is formed by sputtering.

15. The method for forming a metal wiring layer of a semiconductor device of claim 1, wherein the nucleation liner is formed to have a thickness of 10-100 A.

16. The method for forming a metal wiring layer of a semiconductor device of claim 1, wherein the aluminum liner is formed by selective metal organic chemical vapor deposition using a precursor of one of dimethylaluminum hydride (DMAH), trimethylamine alane (TMAA), dimethylethylamine alane (DMEAA), and methylpyrrolidine alane (MPA).

17. The method for forming a metal wiring layer of a semiconductor device of claim 1, wherein forming the metal layer is performed in a vacuum state which has been maintained since forming the aluminum liner.

18. The method for forming a metal wiring layer of a semiconductor device of claim 1, wherein the metal layer is formed of one of aluminum and an aluminum alloy.

19. The method for forming a metal wiring layer of a semiconductor device of claim 1, wherein the metal layer is formed by direct current magnetron sputtering.

20. The method for forming a metal wiring layer of a semiconductor device of claim 1, wherein the step of heat-treating the metal layer is performed at a temperature of 350-500° C.

21. The method for forming a metal wiring layer of a semiconductor device of claim 1, further comprising forming an interlayer dielectric layer to define a hole region on the semiconductor substrate before forming the barrier metal layer,
wherein the barrier metal layer is formed on the semiconductor substrate including the interlayer dielectric layer.

22. The method for forming a metal wiring layer of a semiconductor device of claim 21, wherein the hole region is one of a contact hole, a via hole and a groove having a depth smaller than a thickness of the interlayer dielectric layer.

23. The method for forming a metal wiring layer of a semiconductor device of claim 21, wherein the hole region is a contact hole exposing one of a source/drain region of the semiconductor substrate and a conductive layer.

24. The method for forming a metal wiring layer of a semiconductor device of claim 21, wherein the hole region is a via hole exposing a metal wiring layer on the semiconductor substrate.

25. The method for forming a metal wiring layer of a semiconductor device of claim 21, wherein forming the metal layer is performed to completely fill the hole region by using the metal layer.
